(19) United States
(12) Patent Application Publication
(10) Pub. No.: US 2025/0204289 A1
(43) Pub. Date: Jun. 19, 2025

(54) METHOD FOR MANUFACTURING A MEMORY DEVICE

(71) Applicant: COMMISSARIAT A L'ENERGIE ATOMIQUE ET AUX ENERGIES ALTERNATIVES, Paris (FR)

(72) Inventor: Gabriel PARES, Grenoble Cedex (FR)

(73) Assignee: COMMISSARIAT A L'ENERGIE ATOMIQUE ET AUX ENERGIES ALTERNATIVES, Paris (FR)

(21) Appl. No.: 18/981,096

(22) Filed: Dec. 13, 2024

(30) Foreign Application Priority Data
Dec. 13, 2023 (FR) 2314090

(51) Int. Cl. H10N 70/00

(52) U.S. Cl. CPC H10N 70/8833; H10N 70/023; H10N 70/026; H10N 70/063; H10N 70/066; H10N 70/841

(57) ABSTRACT

The invention relates to a memory device including a plurality of memory points. The device has a plurality of first electrodes and a plurality of second electrodes, each second electrode being located at least partially facing a first electrode. The device also includes an active layer extending continuously between the plurality of first electrodes and the plurality of second electrodes. Each first electrode, a second electrode being located at least partially facing said first electrode, and an active layer portion extending between the first electrode and the second electrode together form a memory point.

### TECHNICAL FIELD

The present invention relates to non-volatile resistive memories integrated in an interconnecting array, for example, of a CMOS (Complementary Metal Oxide Semiconductor)-type technology. It can apply to different types of resistive memories and, in particular, to oxide-based resistive memories (OxRAM), to resistive memories with the basis of a ferroelectric (FeRAM), to conductive bridge resistive memories (CBRAM).

### PRIOR ART

As illustrated in FIG. 1, the memory points 1000′ of non-volatile resistive memories are conventionally constituted of three stacked elements: a lower conductive electrode 120′, an active layer 150′, the properties of which enable a state change in order to store information, and an upper conductive electrode 220′.

In the case of an OxRAM-type resistive memory, the active layer is with the basis of a dielectric. The application of an electric field to the terminals of the lower and upper electrodes makes it possible to break or form a conductive filament within the dielectric layer and thus pass from a high-resistivity state to a low-resistivity state of the dielectric layer, these two states corresponding respectively to the “0” information (or “OFF” state) and to the “1” information (or “ON” state) of the memory.

The integration of such a memory point in an interconnecting array is commonly based on a “mesa”-type structure, in which the memory point is formed along a pattern made by lithography. The connections to the electrodes are commonly made by vias 110′, 210′ connected to metal lines constituting the interconnecting array. Moreover, the mesa structure thus made is then encapsulated by a stack of dielectric layers, then planarised in order to be electrically isolated and to be able to make upper interconnecting levels. This interconnecting array preferably forms part of the layers qualified as BEOL (Back End Of Line).

In order to increase the density of memory points in each of the memory planes, it is sought to reduce the dimensions of the memory points and/or to decrease their spacing. One of the major pitfalls outlined in this regard, is the minimum dimension which is accessible to produce a mesa-type structure. In particular, the size of the memory point is currently determined by the size of the lithography pattern. Yet, the most advanced lithography techniques using extreme ultraviolet (EUV) immersion lithography and DRIE (Dry Reactive Ion Etching)-type plasma etching have, at best, a resolution of around 60 nm to define “mesa”-type structures, i.e. isolated points. The densities of memory points thus obtained are not satisfactory, and there is a need to overcome this dimensional barrier in order to be able to produce more efficient memory devices, and/or memory devices having overall smaller dimensions.

An aim of the present invention is therefore to propose a solution to improve the density of memory points within memory devices.

### SUMMARY

To achieve this aim, a first aim of the invention relates to a memory device comprising a plurality of memory points, the device comprising a plurality of first electrodes and a plurality of second electrodes, each second electrode being located at least partially facing a first electrode, characterised in that it further comprises an active layer extending continuously between the plurality of first electrodes and the plurality of second electrodes, and in that:
each first electrode,
a second electrode being at least partially located facing said first electrode, and
an active layer portion extending between said first electrode and said second electrode,
   together form a memory point.

A second aim of the invention relates to a method for manufacturing a memory device comprising a plurality of memory points, the method comprising the following steps:
Forming a plurality of first electrodes,
Forming an active layer on each of the first electrodes, the active layer being continuous,
   Forming a plurality of second electrodes on the active layer, each second electrode being located at least partially facing a first electrode,
   each first electrode, a second electrode being located at least partially facing said first electrode, and an active layer portion extending between said first electrode and said second electrode, together forming a memory point.

The active layer being common to the plurality of memory points, the memory points thus formed do not require lithography and etching steps to form the active layer, technological steps, the resolution of which is currently limited to 60 nm. The current techniques however make it possible to form electrodes with lithography and etching steps having a resolution going beyond 40 nm. Thus, the method according to the invention can make it possible to greatly increase, typically double, the density of memory points within a memory device.

Moreover, the fact of going without etching for the formation of the pattern of the memory point makes it possible to limit the pattern edge defects due to this manufacturing step. These defects, not very well understood in the prior art, can lead to a deterioration of the performance of the memory device. The method according to the invention therefore makes it possible to produce a memory device with improved performance, with respect to the prior art.

The fact that the active layer is continuous and common to several memory points makes it possible to go without lithography and etching steps, being able to damage the active layer and ultimately lead to worse performance of the memory device. In the scope of the development of the present invention, it has been observed that this pooling of the active layer does not hinder the correct operation of each of the memory points.

Moreover, the device according to the invention comprises a stack comprising, stacked along a so-called stacking direction, in this order:
A first support layer having an upper face, the first support layer comprising a plurality of first holes, each extending from its upper face, each first hole housing:
   i. A first metal via,
   ii. A first electrode of the plurality of first electrodes, each first electrode surmounting a first distinct metal via,
The active layer, surmounting the upper face of the first support layer,
On the active layer, a second support layer comprising a plurality of second holes passing through it, and each opening onto the active layer, each second hole housing:
i. A second metal via,
   ii. A second electrode of the plurality of second electrodes, said second electrode being disposed between the second metal via and the active layer, and being located at least partially facing a first electrode from among the plurality of first electrodes.

Similarly, in the method according to the invention, the step of forming the plurality of first electrodes comprises the following steps:
Providing a first support layer, having an upper face and a lower face opposite one another, the first support layer comprising a plurality of first holes, each extending from its upper face and opening onto its lower face,
Forming a first electrode in each first hole of the plurality of first holes,
   the active layer being formed on the upper face of the first support layer,
   the method further comprising a formation step in each first hole of a first metal via, the first electrode being located in contact with the first metal via.

The method further comprises the following steps:
Forming a second support layer on the active layer, the second support layer comprising a plurality of second holes passing through the second support layer and each opening onto the active layer, each second hole being located at least partially facing a first different electrode,
Forming in each second hole of the plurality of second holes, a second electrode of the plurality of second electrodes and a second metal via, the second electrode being located in contact with the second metal via.

The memory points thus formed only thus require the formation of holes in the first support layer and in the second support layer. The current techniques make it possible to form holes such as those formed in this advantageous embodiment of the method according to the invention with a resolution going beyond 40 nm.

The first holes and the second holes moreover preferably each have a continuous profile along the stacking direction.

The advantages presented in reference to the method according to the second aspect of the invention apply mutatis mutandis to the device according to the first aspect of the invention.

### BRIEF DESCRIPTION OF THE FIGURES

The aims, objectives, as well as the features and advantages of the invention will best emerge from the detailed description of an embodiment of the latter which is illustrated by the following accompanying drawings, in which:

FIG. 1 represents memory points according to the prior art within an interconnecting array.

FIGS. 2A to 2M illustrate an embodiment of the method according to the invention.

FIG. 3 illustrates an embodiment in which two memory points share an electrode and a via.

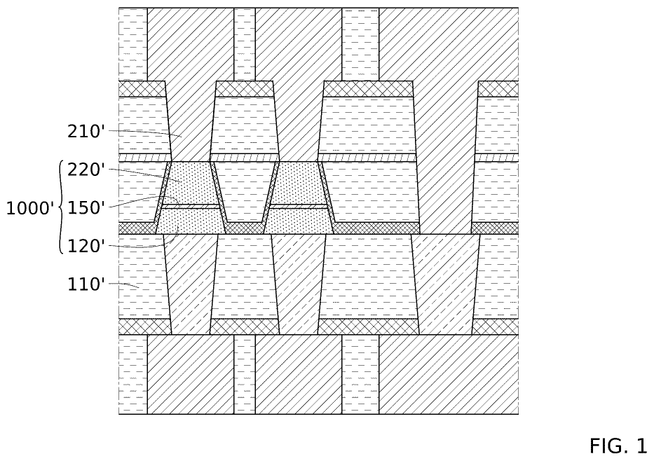

The drawings are given as examples and are not limiting of the invention. They constitute principle schematic representations intended to facilitate the understanding of the invention, and are not necessarily to the scale of practical applications. In particular, the relative dimensions and thicknesses are not representative of reality.

### DETAILED DESCRIPTION

Before starting a detailed review of embodiments of the invention, optional features are stated below, which can optionally be used in association or alternatively:

According to a preferred embodiment, the first holes each have a continuous profile along the stacking direction, projecting into any plane comprising the stacking direction. According to a preferred embodiment, the second holes each have a continuous profile along the stacking direction, projecting into any plane comprising the stacking direction. According to an example, each second electrode is in direct contact with the active layer.

According to an embodiment, at least one first electrode from among the plurality of first electrodes is located at least partially facing at least two second electrodes.

According to an alternative embodiment, each of the first electrodes is located facing one single second electrode.

According to an example, the first metal via and the first electrode contained in one same first hole are with the basis of distinct materials. According to an example, the second metal via and the second electrode contained in one same first hole are with the basis of distinct materials. According to an example, the first metal via is with the basis of one from among the following materials: W, WN, Ru, Co, Ni, Cu, a combination of layers comprising these materials or an alloy of these materials. According to an example, the second metal via is with the basis of one from among the following materials: W, WN, Ru, Co, Ni, Cu, a combination of layers comprising these materials or an alloy of these materials.

According to an example, the first electrode is with the basis of one from among the following materials: TiN, Ti, TaN, W, WN, Ru, C, Si, Co, Ni, a combination of layers comprising these materials or an alloy of these materials. According to an example, the second electrode is with the basis of one from among the following materials: TiN, Ti, TaN, W, WN, Ru, C, Si, Co, Ni, a combination of layers comprising these materials or an alloy of these materials.

According to an example, the device further comprises a protective layer between the active layer and the second support layer.

According to an example, the active layer is with the basis of a dielectric, for example, one from among the following materials:
SiOₓ with x equal to 1 or 2, such as SiO₂,
HfOₓ with x equal to 1 or 2, such as HfO₂,
Al₂O₃,
TiO₂,
Ta₂O₅,
ZrO₂,
an alloy of these elements.

According to an example, the active layer is with the basis of a ferroelectric material, for example, one from among HfₓZr₁₋ₓO₂ with 0<x<1, Si-doped HfO₂, AIScN and a lead zirconate titanate (PZT). In the case of an Si-doped HfO₂-based active layer, Si is preferably present in a concentration less than or equal to 10 atomic %, preferably substantially equal to 1 atomic %.

According to an example, the active layer comprises a solid electrolyte, for example, with the basis of one from among: silver-doped germanium sulphide, and copper-doped germanium sulphide.

According to an advantageous example, each first electrode is flush with the upper face of the first support layer.

According to an embodiment, the device further comprises a plurality of first secondary electrodes and a plurality of second secondary electrodes, each second secondary electrode being located at least partially facing a first secondary electrode, the device further comprising a secondary active layer extending continuously between the plurality of first secondary electrodes and the plurality of second secondary electrodes, and:
each first secondary electrode,
a second secondary electrode being located at least partially facing said first secondary electrode, and
a secondary active layer portion extending between said first secondary electrode and said second secondary electrode together form a secondary memory point.

According to a preferred example, each memory point is an oxide-based resistive memory (OxRAM).

It is understood that two elements are isolated from one another, if they are not in direct contact and are separated from one another by a medium or a material having an electric resistivity greater than 10⁶ Ω·m.

According to an advantageous embodiment, the first support layer comprises at least one first contact hole, the second support layer comprises at least one second contact hole, the first contact hole and the second contact hole being at least partially facing one another, the method further comprising the following steps:
Forming, in the first contact hole, a first contact metal via,
Forming, in the second contact hole, a second contact metal via, the first contact metal via and the second contact metal via being in electric conduction.

It is understood that two elements are in electric conduction when they are in direct contact, or in contact through so-called conductive layers typically having a resistivity less than 150 μΩ·cm. The first contact metal via and the second contact metal via are preferably in direct contact. According to a variant, the first contact metal via and the second contact metal via are in contact through at least one metal layer, typically a first contact electrode and/or a second contact electrode.

According to an example, the first metal via and the first electrode being located in one same first hole are formed during one same deposition step.

According to an advantageous example, the formation of the second support layer comprises a step of depositing the support layer and a formation step in the support layer of the plurality of first holes, the method further comprising, after the formation of the second support layer on the active layer, and before the formation in each second hole of the second metal via and of the second electrode, a step of treating the active layer through second holes, the step of treating the active layer, preferably taking place at one from among the following times:
Before the formation of the second support layer,
After the deposition of the second support layer and before the formation of the plurality of first holes,
After the formation of the plurality of first holes.

According to an example, the method further comprises, after the formation of the active layer, and before the formation of the second support layer, the formation of a protective layer on an upper face of the active layer.

According to an example, the method further comprises, after the formation of the second support layer on the active layer, a removal of portions of the protective layer visible through the second holes. It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first layer on a second layer, does not compulsorily mean that the two layers are directly in contact with one another, but means that the first layer covers, at least partially, the second layer by being, either directly in contact with it, or by being separated from it by at least one other layer or at least one other element.

A layer can moreover be composed of several sublayers of one same material or of different materials.

By a substrate, a layer, a device “with the basis” of a material M, this means a substrate, a layer, a device comprising this material M only or this material M and optionally other materials, for example, alloy elements, impurities or doping elements. Thus, a material with the basis of a III-N material can comprise a III-N material added with dopants.

By “selective etching with respect to” or “etching having a selectivity with respect to”, this means an etching configured to remove a material A or a layer A with respect to a material B or a layer B, and having an etching speed of the material A greater than the etching speed of the material B. The selectivity is the ratio between the etching speed of the material A over the etching speed of the material B. The selectivity between A and B is referenced SA:B.

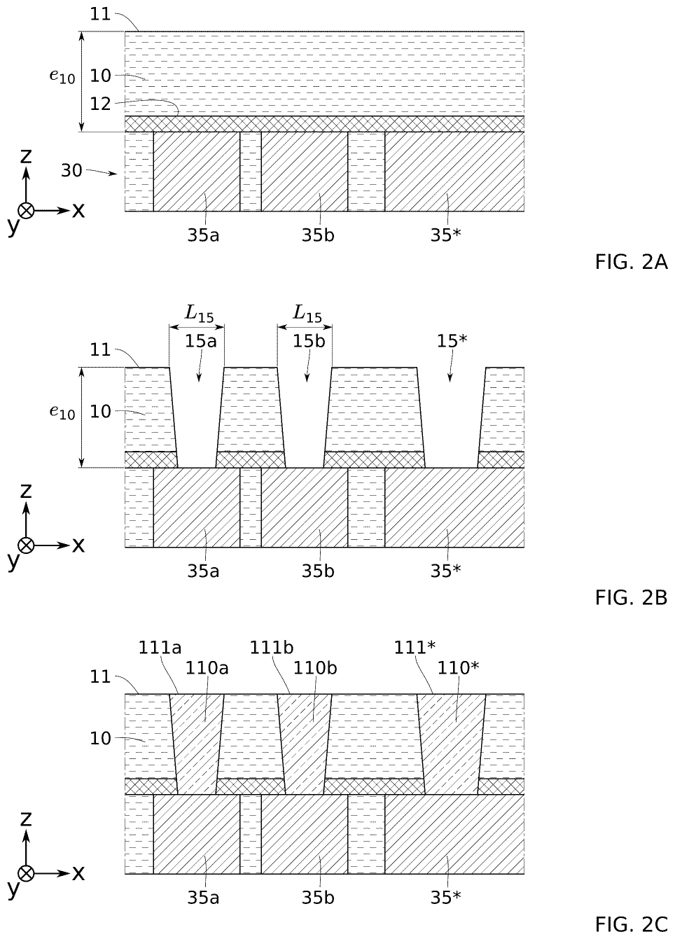

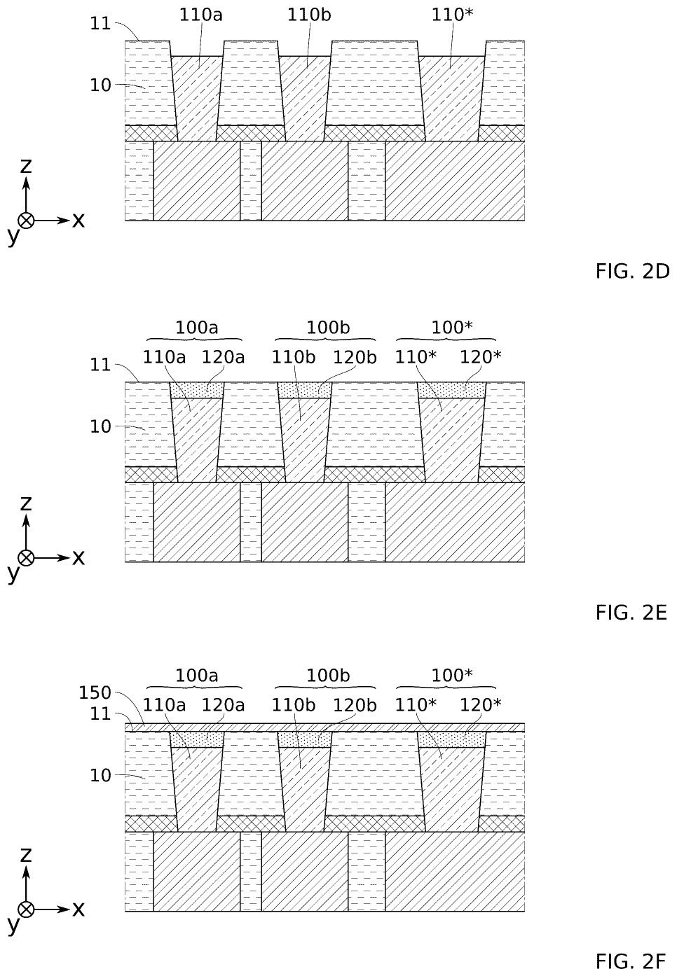

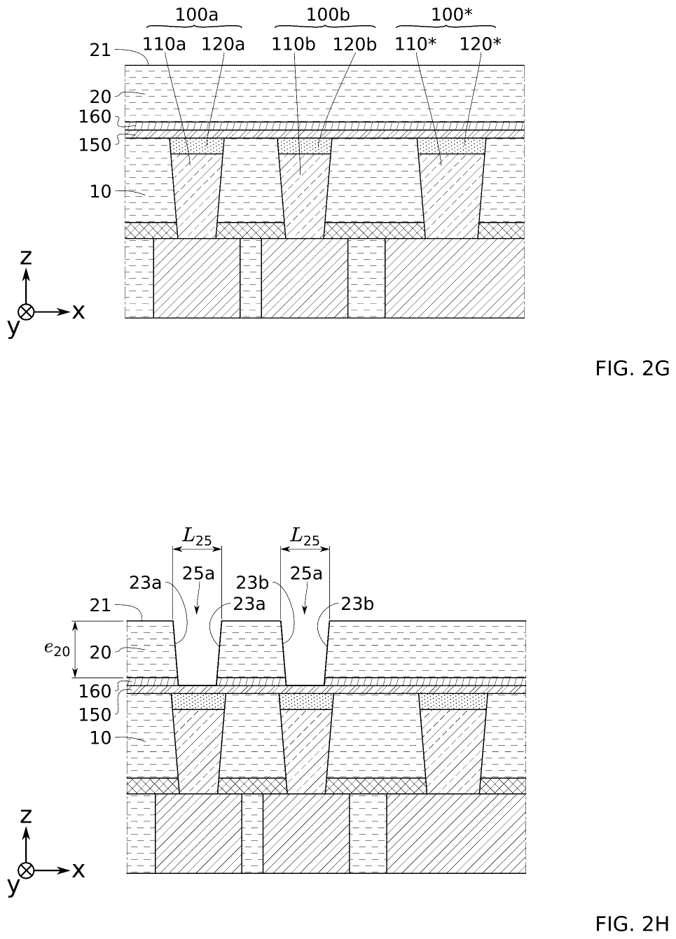

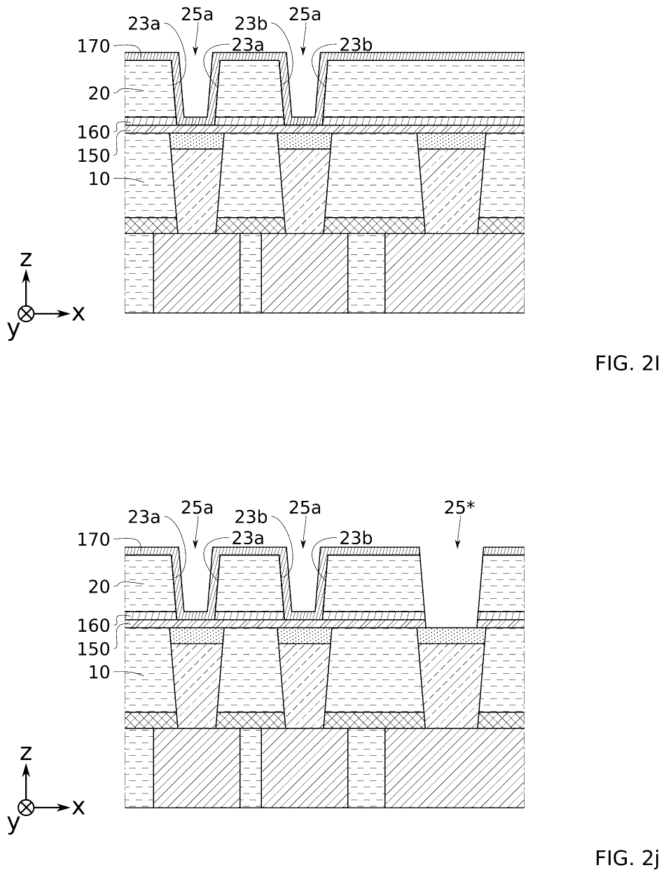

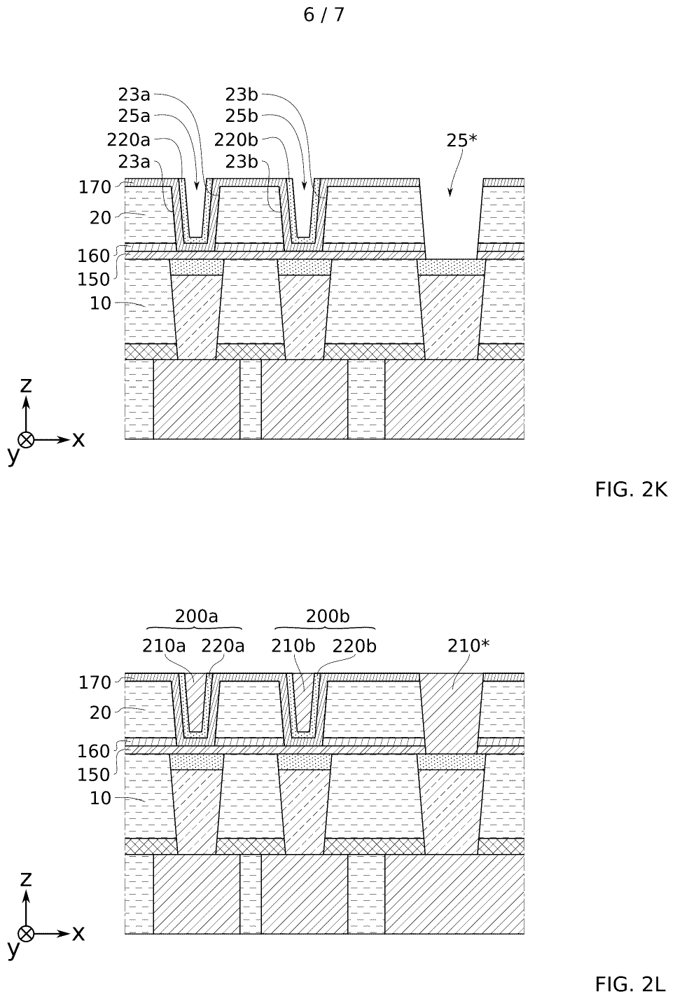

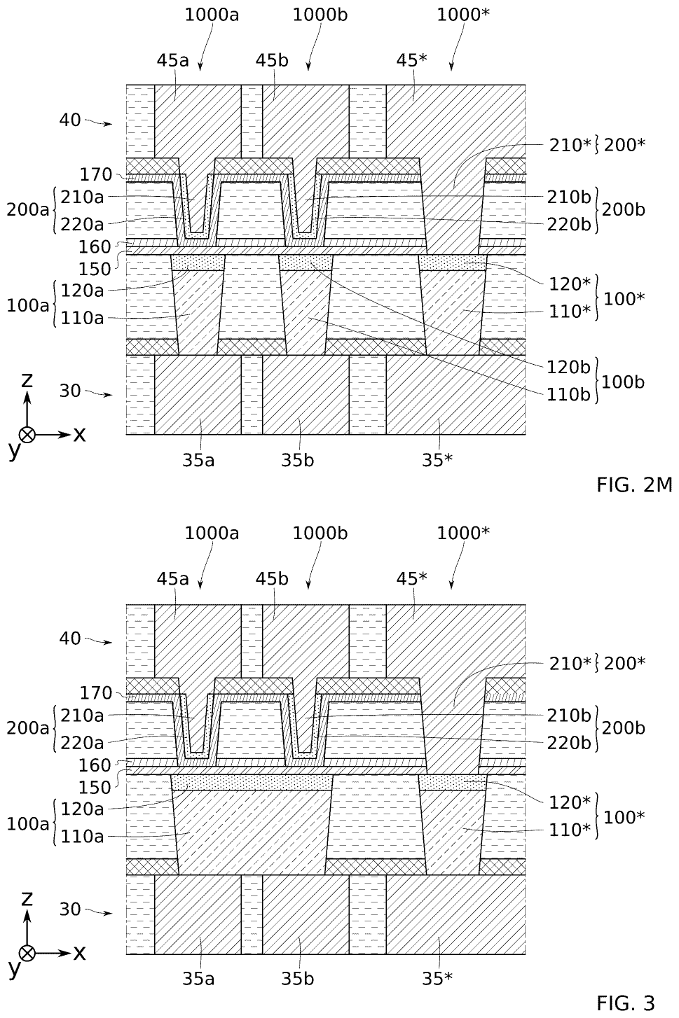

A preferably orthonormal system, comprising the axes X, Y, Z is represented in FIGS. 2A to 2K. The direction Z can be called “stacking direction”.

In the present patent application, preferably thickness will be referred to, for a layer and a height for a structure or a device. The height is taken perpendicularly to the horizontal plane XY. The thickness is taken along a direction normal to the main extension plane of the layer. Thus, a layer typically has a thickness along Z, when it extends mainly along the horizontal plane XY, and a projecting element, for example, an isolation trench, has a height along Z. The relative terms “on”, “under”, “underlying” refer preferably to positions taken along the direction Z.

The terms “substantially”, “about”, “around” mean “plus or minus 10%, preferably 5%”.

An embodiment of the method according to the invention will now be described in reference to FIGS. 2A to 2K. For reasons of clarity, these figures illustrate the obtaining of two memory points only. Naturally, these steps can make it possible to simultaneously obtain numerous memory points from one same first support layer, from one same active layer and from one same second support layer.

FIG. 2A illustrates the provision of a stack comprising, in particular, a first support layer 10. This first support layer 10 can rest, as is illustrated, on any support 30 which is suitable for the applications considered. This can typically be a line comprising metal connection elements 35a, 35b, of the “BEOL” (Back End Of Line) type. This support 30 can be qualified as a lower metal line or also a lower interconnecting line. The support 30 can also comprise other metal levels. The support 30 can further comprise transistors.

The first support layer 10 has a lower face 12 facing this support 30, as well as an upper face 11 opposite the lower face 12. As illustrated in FIG. 2B, holes called first holes 15a, 15b are then formed in the first support layer 10 from its upper face 11.

Preferably, the first holes 15a, 15b pass through the first support layer 10 over its entire thickness e₁₀ along the direction Z. Advantageously, each first hole 15a, 15b opens onto a metal interconnection 35a, 35b of the lower metal line 30. It can also be considered that initially, the first holes 15a, 15b do not open onto the lower face 12 of the first support layer 10. It will be possible, after the formation of the memory points 1000a, 1000b, to polish or grind (for example, by chemical-mechanical polishing—CMP) this lower face 12 in order to make the first metal vias 110a, 110b flush with the latter, the formation of which will be described further. The assembly with the lower metal line 30 thus takes place after this polishing step.

The first holes 15a, 15b can, for example, be formed by lithography and etching. This is, preferably, an anisotropic etching, such as a reactive ion etching or a plasma etching.

The profile of the first holes 15a, 15b is preferably continuous. In particular, the profile of the first holes 15a, 15b is continuous along a direction perpendicular to the upper face 11 of the first support layer 10 (in this case, the stacking direction Z). By continuous profile, this means a profile not having any sudden cross-sectional change in the horizontal plane XY along the stacking direction Z. Such a change can, for example, be called disconnection. Such a disconnection is, for example, obtained when a first layer is etched according to a certain pattern, then that a second layer is deposited on the first layer according to another pattern. In other words, each first hole 15a, 15b defines a continuous surface, this surface corresponding to the delimitation by the first support layer 10 of said first hole 15a, 15b. In particular, by projecting the profile into any plane perpendicular to the horizontal plane XY, this profile is continuous along the stacking direction Z. Thus, by crossing the first hole 15a, 15b from the upper face 11 up to the lower face 12, a curve is defined, preferably a straight line. This curve does not have a corner. This straight line can be vertical or preferably oblique in a plane containing Z, as illustrated in the figures. Advantageously, the surface defined by each first hole 15a, 15b in the first support layer 10 has a symmetry of revolution about an axis parallel to the stacking direction Z.

The profile of the first holes 15a, 15b can be constant or not along the stacking direction Z. A hole having a constant profile is a hole, the cross-section of which in the horizontal plane XY is constant over the entire height along Z of the hole. On the contrary, a hole not having a constant profile is a hole, the cross-section of which in the horizontal plane XY varies along the height of the hole.

The first holes 15a, 15b each have, in the horizontal plane XY, a maximum dimension L₁₅. In the typical case of holes having, projecting into the horizontal plane XY, a circular shape, their maximum dimension corresponds to their diameter. If a hole does not have a constant cross-section along the stacking direction Z, then it is considered that L₁₅ corresponds to the maximum diameter (or other characteristic dimension) taken through this hole along the direction Z. Preferably, L₁₅ is less than 200 nm, preferably less than 100 nm, and even more advantageously, less than 50 nm. L₁₅ can, in particular, be substantially equal to 40 nm.

According to an advantageous embodiment, at least one first contact hole 15* is also formed in the first support layer 10 from its upper face 11. The first contact hole 15* and the first holes 15a, 15b are preferably formed simultaneously, during one same etching step. Advantageously, the first contact hole 15* opens onto a metal interconnection 35* of the lower metal line 30.

Thus, the first support layer 10 is obtained, comprising a plurality of first holes 15a, 15b, and preferably at least one first contact hole 15*, which, according to an advantageous embodiment of the method according to the invention, is provided during the first step of the method.

As illustrated by the passage from FIG. 2B to FIG. 2E, a second step of the method consists of the filling of each first hole 15a, 15b with a first metal via 110a, 110b and a first electrode 120a, 120b.

The features described below for a first metal via 110a, 110b and a first electrode 120a, 120b apply to all of the first metal vias 110a, 110b and the first electrodes 120a, 120b.

The first metal via 110a, 110b is preferably in contact with a metal interconnection 35a, 35b of the lower metal line 30. The first electrode 120a, 120b and the first metal via 110a, 110b are in contact.

The first electrode 120a, 120b can be multilayer.

The first electrode 120a, 120b is preferably with the basis of an inert material with respect to the active layer 150, i.e. not contributing to the mechanical for forming and breaking the filament in the active layer, in a particular case, it can favour the creation of a conductive filament within the active layer 150 which will be described further. It can be with the basis of the same material as the first metal via 110a, 110b, or with the basis of a distinct material.

According to a first example illustrated by the sequence of steps illustrated in FIGS. 2B, 2C, 2D and 2E, the first holes 15a, 15b are first fully filled by the first metal via 110a, 110b (FIG. 2C), then a portion of this first metal via 110a, 110b is removed, typically by etching, from its upper face 111a, 111b (FIG. 2D). The space thus left empty by this removal in the first hole 15a, 15b is then at least partially, preferably fully, filled by the first electrode 120a, 120b (FIG. 2E).

According to a second example illustrated by the sequence of steps illustrated in FIGS. 2B, 2D and 2E, the first holes 15a, 15b are first partially filled by the first metal via 110a, 110b (FIG. 2D), then the first electrode 120a, 120b is deposited on the first metal via 110a, 110b (FIG. 2E).

In both cases, the assembly constituted of the first metal via 110a, 110b and of the first electrode 120a, 120b being located in one same first hole 15a, 15b constitutes a first conductive assembly 100a, 100b. Just like the first holes 15a, 15b, the first conductive assemblies 100a, 100b have a continuous profile.

As illustrated in FIGS. 2C to 2E, a first contact metal via 110* and a first contact electrode 120* are formed in the first contact hole 15*, preferably during same deposition and etching steps as the first metal vias 110a, 110b and as the first electrodes 120a, 120b, respectively. It is, however, understood that the first contact hole 15* can accommodate only a first contact metal via 110* or only a first contact electrode 120*. The first contact metal via 110*, the first contact electrode 120* or the assembly of both, as the case may be, constitutes a first contact conductive assembly 100*. The first contact conductive assembly 100* is preferably in contact with a metal interconnection 35* of the lower metal line 30.

The deposition of the first electrodes 120a, 120b, of the first metal vias 110a, 110b, of the first contact metal via 110* and of the first contact electrode 120* can, for example, be made by physical vapour deposition (PVD), or also by chemical vapour deposition (CVD).

It is understood that after the formation of the first metal vias 110a, 110b, of the first contact metal vias 110*, of the first electrodes 120a, 120b, and of the first contact electrodes 120* in the first holes 15a, 15b and in the first contact holes 15*, the first support layer 10 always defines these holes 15a, 15b, 15*, even if these are filled. Thus, below in the present description, a hole formed in the support layer 10 can therefore mean an empty hole or a filled hole.

As illustrated in FIG. 2F, during a third step of the method, an active layer 150 is formed on the upper face 11 of the first support layer 10 and on, and preferably in contact with, each of the first electrodes 120a, 120b. The active layer 150 thus extends above a plurality of first conductive assemblies 100a, 100b. The active layer 150 is continuous, thus there is continuity of material between the portions of the active layer 150 overlooking the different first conductive assemblies 100a, 100b.

The active layer 150 can be multilayer. It is preferably monolayer.

Moreover, at this stage of the method, the active layer 150 preferably also covers the first contact conductive assembly 100*. Indeed, depositing the active layer 150 over the entire surface of the stack (so-called “full-wafer” deposition) makes it possible to simplify the method.

The active layer 150 is with the basis of a material being able to selectively pass from a first state having a first resistivity to a second state having a second resistivity, different from the first. Preferably, the first resistivity is greater than 2 times, preferably 10 times, and preferably 100 times, the second resistivity.

At this stage, it is possible to proceed with a step of treating the active layer 150. This can be a surface treatment, or an effective treatment in the entire thickness of the active layer 150. The treatment can, for example, be an ion implantation aiming to modify the properties of the layer favouring the formation or the breaking of the conductive filament. A thermal treatment can also be performed at this stage to relax the stresses in the active layer 150 and thus limit the structural defects being able to be present after the deposition, or also modify the structure of the active layer 150, in order to favour the formation or the breaking of the conductive filament. In particular, this thermal treatment can make it possible to pass from an amorphous state of the active layer 150 to a crystalline state, which can be preferably sought in the case of an FeRAM-type memory. This treatment can be done in a wafer-scale furnace.

Advantageously, a protective layer 160 is formed on the active layer 150. This protective layer 160 can, for example, be SiN—, SiCN—, carbon-based, or with the basis of any other material offering a good etching selectivity both with respect to the second support layer 20 described further and to the active layer 150, such that it will be possible to etch the second holes 25a and 25b by stopping on this layer 160, and without damaging the active layer 150, then to remove the portions of the layer 160 exposed in the bottoms of the second holes 25a and 25b by a method making it possible to slightly, even not degrade the first electrodes 120a, 120b.

FIG. 2G illustrates the deposition of a second support layer 20 on the active layer 150. This second support layer 20 indirectly covers at least the plurality of holes 15a, 15b, from now on filled by the plurality of first conductive assemblies 100a, 100b. It also advantageously covers the first contact conductive assembly 100*. If a protective layer 160 has been deposited beforehand on the active layer 150, the second support layer 20 also covers it, preferably by being in contact with it.

After the formation of the second support layer 20, it is possible to perform a treatment step. This can, in particular, be a thermal treatment such as described above. When this thermal treatment is performed at this stage of the method, the second support layer 20 makes it possible to protect the active layer 150 during the treatment.

As illustrated in FIG. 2H, a plurality of second holes 25a, 25b is then formed in the second support layer 20, from its upper face 21. The second holes 25a, 25b each pass through the second support layer 20 over its entire thickness e₂₀ along the direction Z. Each second hole 25a, 25b thus opens onto the active layer 150 and is located facing a first distinct hole 15a, 15b.

If a protective layer 160 is present between the active layer 150 and the second support layer 20, the second holes 25a, 25b also pass through the protective layer 160 over its entire thickness along the direction Z. The formation of the second holes 25a, 25b can thus be done in two steps: a first etching in the second support layer 20 and a second etching in the protective layer 160. The protective layer 160 thus protects the active layer 150 during the etching of the second holes 25a, 25b in the second support layer 20. It is, itself, advantageously removed locally, thanks to a method which is very slightly damaging, even not damaging to the active layer 150, for example, a chemical etching or RIE (Reactive Ion Etching) selectively to the active layer. The presence of the protective layer 160 and the formation of the second holes 25a, 25b in two successive and distinct removal steps thus make it possible to limit the degradation of the active layer 150. This makes it possible to optimise the performance of the memory points obtained at the end of the method.

As for the first holes 15a, 15b, the profile of the second holes 25a, 25b is continuous and can be constant or not along the stacking direction Z.

The second holes 25a, 25b each have, in the horizontal plane XY, a maximum dimension L₂₅. In the typical case of holes having, projecting into the horizontal plane XY, a circular shape, their maximum dimension corresponds to their diameter. If a hole does not have a constant cross-section along the stacking direction Z, then it is considered that L₁₅ corresponds to the maximum diameter (or other characteristic dimension) taken by this hole along the direction Z. Preferably, L₂₅ is less than 200 nm, preferably less than 100 nm, and even more advantageously less than 50 nm. L₂₅ can, in particular, be substantially equal to 40 nm. It must be noted that the second holes 25a, 25b can have a maximum dimension L₂₅ different from the maximum dimension L₁₅ of the first holes.

At this stage, it is possible to proceed with a step of treating the active layer 150 through second holes 25a, 25b. More precisely, the treatment is effective at the portions of the active layer 150 visible through the second holes 25a, 25b. This can be a surface treatment, or an effective treatment in the entire thickness of the active layer 150. The treatment can, for example, be an ion implantation aiming to modify the properties of the layer favouring the formation or the breaking of the conductive filament. A thermal treatment can also be performed at this stage to relax the stresses in the active layer 150, and thus limit the structural defects being able to be present after the deposition or after the etching of the holes 25a, 25b, or also modify the structure of the active layer 150, in order to favour the formation or the breaking of the conductive filament. In particular, this thermal treatment can make it possible to pass from an amorphous state of the active layer 150 to a crystalline state, which can be sought preferably in the case of an FeRAM-type memory. This treatment can be done in a wafer-scale furnace or by using a LASER locally at the second holes 25a, 25b.

At this stage, it is also possible to deposit a second active layer 170 over the entire exposed surface of the stack, namely on the upper face 21 and the internal flanks 23a, 23b of the support layer 20 and on the portions of the active layer 150 visible through the second holes 25a, 25b. This second active layer 170 can advantageously improve the performance of the memory point in association with the first active layer 150. This layer 170 is deposited continuously over all of the wafer without needing to be etched (except for a portion which will be etched during the formation of the second contact hole 25* described below).

According to an advantageous embodiment, at least one second contact hole 25* is also formed in the second support layer 20 from its upper face 11, and, if they have been deposited beforehand, in the protective layer 160, and in the second active layer 170. Likewise, if the active layer 150 has been deposited beforehand, until on the first conductive assembly 100*, the second contact hole 25* also passes through the active layer 150.

The second contact hole 25* is formed independently from the second holes 25a, 25b in order to etch the active layer 150 and optionally the protective layer 160 only in this second contact hole 25* the zones of the active layer 150 or of the protective layer 160 visible through the second holes 25a, 25b thus being protected.

According to another advantageous embodiment, the second contact hole 25* can be formed before the second holes 25a, 25b. This makes it possible to not risk damaging the active layer 150 during the production of the second contact hole 25*.

According to another advantageous embodiment, the second contact hole 25* can be formed partially during the formation of the second holes 25a, 25b. In this case, the second holes 25a, 25b and second contact hole 25* are etched at the same time in the support layer 20 (and in the protective layer 160 if it is present) up to the active layer 150, then another protection is implemented above the second holes 25a, 25b to etch the active layer 150 only in the second contact hole 25*.

The second contact hole 25* and the first contact hole 15* are located opposite one another, and make it possible to ensure the passage of the current between the lower levels and the upper levels of the circuit.

Thus, the second support layer 20 is obtained, comprising a plurality of second holes 25a, 25b, and preferably at least one second contact hole 25*, which is formed during the fourth step of the method according to the invention.

As illustrated by FIGS. 2I and 2J, a fifth step of the method consists of the filling of each second hole 25a, 25b with a second metal via 210a, 210b and a second electrode 220a, 220b.

The features described below for a second metal via 210a, 210b and a second electrode 220a, 220b apply to all of the second metal vias 210a, 210b and the second electrodes 220a, 220b.

The second electrode 220a, 220b can be deposited directly on the active layer 150, optionally as well as against the internal flank 23a, 23b of the second support layer 20 defining the hole 20a, 20b in which it is deposited. If a second active layer 170 has been deposited on the active layer 150 and on the internal flank 23a, 23b of the second support layer 20, the second electrode 220a, 220b will be deposited on the second active layer 170. In any case, the second electrode 220a, 220b thus defines a cavity in which the second metal via 210a, 210b can be deposited.

Whatever the shape chosen for the second electrode 220a, 220b, the second electrode 220a, 220b and the second metal via 210a, 210b are in contact.

The second electrode 220a, 220b can be multilayer. It is preferably monolayer.

The second electrode 220a, 220b is preferably with the basis of a material favouring the creation of a conductive filament within the active layer 150. It can be with the basis of the same material as the second metal via 210a, 210b, or with the basis of a distinct material.

The assembly constituted of the second metal via 210a, 210b and of the second electrode 220a, 220b being located in one same second hole 25a, 25b constitutes a second conductive assembly 200a, 200b. Just like the second holes 25a, 25b, the second conductive assemblies 200a, 200b have a continuous profile.

As illustrated in FIG. 2J, a second contact metal via 210* and optionally a second contact electrode 220* (not represented) can be formed in the second contact hole 25*, preferably during the same deposition and etching steps as the second metal vias 210a, 210b and as the second electrodes 220a, 220b, respectively. The second contact metal via 210*, optionally with the second contact electrode 120*, constitute(s) a second contact conductive assembly 200*.

The deposition of the second electrodes 220a, 220b, of the second metal vias 210a, 210b, of the second contact metal via 210* and of the second contact electrode 220* can, for example, be done by physical vapour deposition (PVD), or also by chemical vapour deposition (CVD).

As illustrated in FIG. 2K, a layer or line 40 can be formed on the second support layer 20 and on the second conductive assemblies 200a, 200b. This is, typically, a line comprising metal connection elements 45a, 45b, of the “Back End Of Line” or “BEOL” type. This line 40 can be qualified as an upper metal line or also, as an upper interconnecting line.

Each second metal via 210a, 210b is preferably in contact with a metal interconnection 45a, 45b of the upper metal line 40. Moreover, the second contact conductive assembly 200* is preferably in contact with a metal interconnection 45* of the upper metal line 40.

Each assembly constituted of a first electrode 120a, 120b and of a second electrode 220a, 220b facing one another, as well as the active layer 150 portion separating them, form a memory point 1000a, 1000b.

Moreover, each assembly constituted of a first contact conductive assembly 100* and of a second contact conductive assembly 200* facing one another form a contact point 1000* or contact via 1000*. This contact via 1000* is fully electrically conductive. It thus enables the passage of the current from a level of the interconnecting array to the directly upper or lower level.

According to an embodiment illustrated in FIG. 3, it is possible that several memory points 1000a, 1000b have a common conductive assembly, whether the first conductive assembly 100a or the second conductive assembly 100b. In other words, one same first metal via 110a and one same first metal electrode 120a, or one same second metal via 210a and one same second metal electrode 220a can form part of several memory points 1000a, 1000b.

In the example illustrated in FIG. 3, two memory points 1000a, 1000b have the same first conductive assembly 100a. This extends below two distinct conductive assemblies 200a, 200b. To obtain such a device, only the sizing and the positioning of the first holes 15a, 15b is to be modified with respect to an embodiment in which all the memory points are constituted of distinct first conductive assemblies 100a, 100b and of second conductive assemblies 200a, 200b.

The structure illustrated in FIG. 3 corresponds to a so-called 1T2R structure. It is understood that it can be considered to form any structure of the 1TnR type, n being an integer greater than 2, n corresponding to the number of second conductive assemblies being located facing one same first conductive assembly.

The case 1T1R corresponds to the embodiment illustrated in FIG. 2M.

In the case of a 1TnR structure, each second via 200a, 200b is preferably connected to an independent upper line (typically called “bit line”), making it possible to apply a particular bias to each memory point 1000a, 1000b during the reading or the writing of one of the n memory points thus formed.

It is understood that the designations “lower” and “upper” are not intended in a limiting sense, in particular as regards the order of performing the method. It can absolutely be considered that the first support layer 10 is initially deposited on an interconnecting line which will have a role as an upper metal line, and that the second support layer 20 is covered with an interconnecting line which will have a role as a lower metal line within a BEOL-type interconnecting array.

It appears, regarding the different embodiments described, that thanks to the formation of the vias and electrodes within the first and second holes, the invention makes it possible to increase the density of memory points within a device. In particular, it is possible, thanks to the invention, to obtain greater densities of memory points, by forming them by “mesa”-type structures.

Further to the greater densities of memory points obtained thanks to the invention, another defect of the “mesa”-structure memory points is avoided. Indeed, when “mesa”-type structures are formed, to obtain an acceptable density of memory points, structures having a height greater than their diameter are opted for (high form factor is referred to, typically greater than 1:1), as well as the spacing between structures. Thus, the problem of encapsulating these memory point matrices, by an isolating layer, without leaving holes, is posed. These holes can indeed create integration problems, during planarisation, for example, or also reliability of the device. By integrating the vias and electrodes in the holes formed within the continuous layers 10, 20, the step of encapsulating and planarising the memory points is avoided, and there is no longer a risk of forming undesired holes between the memory points.

The invention is not limited to the embodiments described above, and extends to all the embodiments covered by the invention.

1. A memory device comprising a plurality of memory points, the device comprising a plurality of first electrodes, a plurality of second electrodes, each second electrode being located at least partially facing one of the plurality of first electrodes, and an active layer extending continuously between the plurality of first electrodes and the plurality of second electrodes, wherein:
each first electrode,
a second electrode being located at least partially facing said first electrode, and
an active layer portion extending between said first electrode and the second electrode being located at least partially facing said first electrode
together form a memory point,
the device comprising a stack comprising, stacked along a stacking direction, in this order:
a first support layer having an upper face, the first support layer comprising a plurality of first holes each extending from its upper face, each first hole housing:
i. a first metal via, and
ii. a first electrode of the plurality of first electrodes, each first electrode surmounting a distinct first metal via,
the active layer, surmounting the upper face of the first support layer,
on the active layer, a second support layer comprising a plurality of second holes passing therethrough and each opening onto the active layer, each second hole housing:
iii. a second metal via, and
iv. one second electrode of the plurality of second electrodes, the one second electrode being disposed between the second metal via and the active layer, and being located at least partially facing a first electrode from among the plurality of first electrodes.

2. The memory device according to claim 1, wherein the first holes each have a continuous profile along the stacking direction projecting into any plane comprising the stacking direction.

3. The memory device according to claim 1, wherein the second holes each have a continuous profile along the stacking direction projecting into any plane comprising the stacking direction.

4. The memory device according to claim 1, wherein each second electrode is in direct contact with the active layer.

5. The memory device according to claim 1, wherein at least one first electrode from among the plurality of first electrodes is located at least partially facing at least two second electrodes.

6. The memory device according to claim 1, wherein each of the first electrodes is located facing a single second electrode.

7. The memory device according to claim 1, wherein the first metal via and the first electrode contained in one same first hole are based upon distinct materials.

8. The memory device according to claim 1, further comprising a protective layer between the active layer and the second support layer.

9. The memory device according to claim 1, wherein each first electrode is flush with the upper face of the first support layer.

10. The memory device according to claim 1, further comprising a plurality of first secondary electrodes and a plurality of second secondary electrodes, each second secondary electrode being located at least partially facing a first secondary electrode, the device further comprising a secondary active layer extending continuously between the plurality of first secondary electrodes and the plurality of second secondary electrodes, wherein:
each first secondary electrode,
a second secondary electrode being located at least partially facing said first secondary electrode, and
a secondary active layer portion extending between said first secondary electrode and said second secondary electrode
together form a secondary memory point.

11. The memory device according to claim 1, wherein each memory point is an oxide-based resistive memory (OxRAM).

12. A method for manufacturing a memory device comprising a plurality of memory points, the method comprising:
forming a plurality of first electrodes,
forming an active layer on each of the first electrodes, the active layer being continuous,
forming a plurality of second electrodes on the active layer, each second electrode being located at least partially facing a first electrode,
each first electrode, a second electrode being located at least partially facing said first electrode, and an active layer portion extending between said first electrode and the second electrode being located at least partially facing said first electrode together forming a memory point,
wherein forming the plurality of first electrodes comprises:
providing a first support layer, having an upper face and a lower face opposite one another, the first support layer comprising a plurality of first holes, each extending from its upper face and opening onto its lower face, and
forming a first electrode in each first hole of the plurality of first holes,
the active layer being formed on the upper face of the first support layer,
forming in each first hole a first metal via, the first electrode being located in contact with the first metal via,
forming a second support layer on the active layer, the second support layer comprising a plurality of second holes passing through the second support layer and each opening onto the active layer, each second hole being located at least partially facing a different first electrode, and
forming, in each second hole of the plurality of second holes, one second electrode of the plurality of second electrodes and a second metal via, the one second electrode being located in contact with the second metal via.

13. The memory device according to claim 12, wherein
forming the second support layer comprises depositing the support layer and forming the plurality of first holes in the support layer, and
the method further comprises, before forming in each second hole the second metal via and the second electrode, treating the active layer.

14. The method according to claim 13, wherein treating the active layer takes place at one of the following times:
before the formation of the second support layer,
after the deposition of the second support layer (20) and before the formation of the plurality of first holes), and
after the formation of the plurality of first holes.
